(19) United States
(12) Patent Application Publication
(10) Pub. No.: US 2025/0004223 A1
(43) Pub. Date: Jan. 2, 2025

(54) PHOTONIC INTEGRATED CIRCUIT WITHIN A CAVITY OF INTERPOSER

(71) Applicant: Intel Corporation, Santa Clara, CA (US)

(72) Inventors: Xiaoqian Li, Chandler, AZ (US); Vidya Jayaram, Chandler, AZ (US); Ravindranath V. Mahajan, Chandler, AZ (US); Saikumar Jayaraman, Chandler, AZ (US)

(73) Assignee: Intel Corporation, Santa Clara, CA (US)

(21) Appl. No.: 18/346,116

(22) Filed: Jun. 30, 2023

(51) Int. Cl. G02B 6/42

(52) U.S. Cl. CPC G02B 6/428; G02B 6/4214

(57) ABSTRACT

An apparatus comprising an interposer to couple conductive contacts of a substrate to conductive contacts of an integrated circuit device, wherein the interposer comprises a cavity proximate conductive contacts of the interposer, the conductive contacts of the interposer to couple to conductive contacts of a photonics integrated circuit (PIC).

### BACKGROUND

A photonic integrated circuit (PIC), sometimes referred to as an integrated optical circuit, is an integrated circuit device that incorporates multiple photonic components to create a functional circuit. For example, a PIC may be capable of detecting, generating, transporting, and/or processing light. Unlike electronic integrated circuits (EICs) that rely on electrons, photonic integrated circuits may utilize particles of light called photons. A PIC may enable the manipulation of information signals carried by optical wavelengths, typically within the visible spectrum or near infrared range.

### BRIEF DESCRIPTION OF THE DRAWINGS

FIG. 1 illustrates example phases of manufacture of an example downward facing PIC within a cavity of an EIC interposer with a silicon substrate.

FIG. 2 illustrates example phases of manufacture of an example downward facing PIC within a cavity of an interposer with a glass substrate.

FIG. 3 illustrates an example upward facing PIC within a cavity of an interposer with a glass substrate.

FIG. 4 illustrates an example PIC and integrated light source within a cavity of an interposer with a glass substrate.

FIG. 5 illustrates another example PIC and integrated light source within a cavity of an interposer with a glass substrate.

FIG. 6 illustrates an example integrated light source and upward facing PIC within a cavity of an interposer with a glass substrate.

FIGS. 7A-7D illustrate example package level integrations for a PIC within a cavity of an interposer.

FIG. 8 illustrates multiple PICs in cavities of an example interposer.

FIG. 9 illustrates multiple PICs in cavities of an example interposer with a glass substrate.

FIG. 10 illustrates an example process for forming a PIC within a cavity of an interposer.

FIG. 11 is a top view of a wafer and dies.

FIG. 12 is a cross-sectional side view of an integrated circuit device.

FIG. 13 is a cross-sectional side view of an integrated circuit device assembly.

FIG. 14 is a block diagram of an example electrical device.

### DETAILED DESCRIPTION

Off-package input/output (I/O) bandwidth has been steadily increasing, approximately doubling every two years. Accordingly, an emphasis has been placed on scaling packaging and I/O technologies to meet this bandwidth demand. As a result, package pin counts and I/O data rates continue to increase. However, the electrical I/O reach (e.g., the length of electrical printed circuit board (PCB) trace or cable) reduces at increased date rates. Additionally, I/O energy efficiency improvement has drastically slowed, leading to a quickly approaching I/O power wall for high-performance packages. Co-package optics solutions have been showing benefit for both power efficiency and bandwidth improvement.

There are several architecture options for co-package optics. For example, a monolithic photonic integrated circuit (PIC) or a PIC-electronic integrated circuit (EIC) stack may be attached to an organic substrate or the PIC may be placed in a cavity of an organic substrate and the EIC may be placed above the PIC. Optical coupling from the PIC to the external world may be implemented through fiber pigtails or fiber array units, but such solutions may have yield and handling (e.g., in both assembly and system integration) challenges for packaging and system integration.

In various embodiments of the present disclosure, a PIC is placed within an open cavity of an interposer. For example, the PIC may be placed within a cavity of an interposer comprising a glass or silicon substrate. In some examples, the interposer may include an integrated light (e.g., laser) source within the cavity or an additional cavity of the interposer or may utilize an external light source (e.g., a light source not connected to the interposer, but included within a component or IC device coupled to the interposer).

Various embodiments described herein may result in one or more technical advantages, such as improved optical coupling, improved yield, reduced warpage or stress impact on the PIC, and/or improved system architecture compatibility.

In some embodiments, yield may be improved. Edge coupling may typically be accomplished through a fiber array unit (FAU) attached to a PIC. However, if the attachment of the FAU to the PIC is not successful, the PIC and the package including the PIC may have to be sacrificed. In some embodiments, pigtails/FAUs are not connected to the PIC and thus wastage of known good PICs may be avoided.

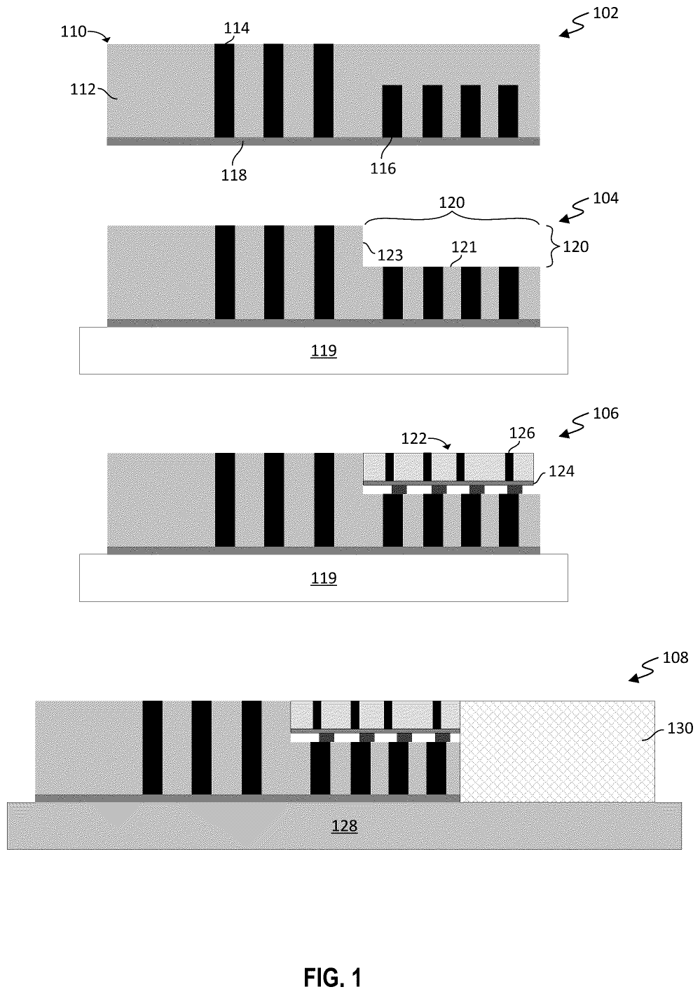

FIG. 1 illustrates example phases of manufacture of an example downward facing PIC within a cavity of an EIC interposer with a silicon substrate. The phases are shown as a cross-cut view of the structure.

In general, an interposer may function as an interconnect bridge connecting two or more integrated circuit devices or components together. In various embodiments, an interposer may spread a connection to a wider pitch or reroute a connection to a different connection. In some embodiments, an interposer may be disposed between and/or couple one or more dies and a package substrate.

An interposer may comprise a substrate material, such as silicon, glass, or organic materials (e.g., laminates or polymers). An interposer may also comprise a network of interconnects (e.g., metal traces, vias, micro-bumps, etc.) that provide electrical paths between IC devices, a package substrate, and/or other components coupled to the interposer. The interposer may have an array of conductive contacts (e.g., solder bumps, micro-bumps, etc.) on its surfaces, providing physical and electrical connections to one or more integrated circuit devices or package substrates. In some implementations, an interposer may also include passive components such as resistors, capacitors, or inductors to facilitate signal conditioning, impedance matching, power delivery, or decoupling. In various implementations, an interposer may also include dielectric layers that provide insulation and isolation between the interconnects and other layers.

In general, EIC interposer 110 may comprise an integrated circuit configured to electrically integrate with a PIC to provide functionality of an optoelectronic assembly. EIC interposer 110 may provide various functions such as one or more of driving, processing, or cleaning signals from and to the PIC or providing power at the desired voltage to the PIC.

Phase 102 depicts an EIC interposer 110 with a substrate 112 comprising silicon (e.g., the substrate may be predominately comprised of silicon, with a small allowance for other elements). The EIC interposer 110 may comprise vias 114 and 116 (e.g., through-silicon-vias enabling power, ground, and/or signal connectivity to components coupled to either side of the substrate 112) with different depths. For example, in the shown phase, the vias 114 may extend to the top of the substrate 112 of EIC interposer 110 while the vias 116 only extend part of the way through the substrate 112 of the EIC interposer 110. The shorter vias 116 may be placed in a region in which a cavity in the EIC interposer 110 is to be formed. The vias may be coupled to conductive contacts on surfaces of the EIC interposer 110.

The EIC interposer 110 also includes an active region 118. The active region 118 may include various components, electrical routing, and/or connections to facilitate the functionality of the EIC interposer. For example, the active region 118 may comprise active components, such as one or more transistors, voltage converters, trans-impedance amplifiers (TIA), clock and data recovery (CDR) components, microcontrollers, or other components configured to operate with electrical signals. In various embodiments, EIC interposer 110 may additionally or alternatively comprise passive circuitry. In some embodiments, the passive circuitry may be sufficient to enable interconnection to the PIC and other components in a package without any active components.

In phase 104, a portion of the substrate 112 of the EIC interposer 110 is removed to form a cavity 120 in the EIC interposer 110. The portion of the substrate 112 may be removed using any suitable method, such as through a dry etch. After cavity 120 is formed, vias 116 may extend up to the bottom of the cavity 120. During this phase, the EIC interposer 110 may be placed on a temporary carrier 119 (e.g., a glass carrier) to provide structure during the various assembly steps.

In various embodiments, the cavity may be formed in any suitable portion of the interposer. For example, the cavity may be formed in the lateral interior of the interposer (e.g., away from the sides such that the cavity is bounded on its sides by four vertical sides (e.g., one of which may be vertical side 123) of the substrate and on its bottom by a lateral surface of the substrate (e.g., surface 121)). As another example, the cavity may be formed proximate one or more vertical sides of the interposer, such that the cavity is then bounded on its vertical sides by less than four vertical sides of the substrate (e.g., only two vertical sides if the cavity is formed in a corner of the interposer).

In phase 106, PIC 122 is placed within cavity 120 and is attached to the EIC interposer 110. The PIC 122 may be attached to the EIC interposer 110 using any suitable method, such as through solder and underfill, thermal compression bonding with non-conductive paste (TCNCP), or a liquid metal socket.

In some embodiments, a singulation step may also be performed during this phase. In various embodiments, the PIC may be attached to the EIC on a wafer level and once the PIC is attached to the EIC, the EIC wafer may be singulated.

In the embodiment depicted, PIC 122 includes an active region 124 and vias 126. In this embodiment, the PIC 122 may be attached to the EIC interposer 110 with the active region 124 facing downwards (e.g., at the bottom of the cavity 120 that is now occupied at least in part by the PIC 122).

In some embodiments, a PIC 122 may be configured to transmit and/or receive an optical signal in an active region 124. Active region 124 may comprise optical elements, such as one or more electromagnetic radiation sources (e.g., lasers, oscillators, light emitting diodes (LEDs)), other optical elements (e.g., polarizers, phase shifters, filters, multiplexers, attenuators, waveguides, or amplifiers), active elements (e.g., transistors), or passive elements (e.g., resistors, capacitors, or inductors). In various embodiments, the elements of the active region 124 may be fabricated using any suitable methods, such as semiconductor photolithographic and deposition methods.

A waveguide, whether present in an active region of a PIC or in another location referenced herein, may guide optical signals. A waveguide may also perform any of coupling, switching, splitting, multiplexing, or demultiplexing optical signals. In some instances, a waveguide may include any component configured to feed, or launch, an electromagnetic signal into a medium of propagation such as an optical fiber.

In phase 108, the EIC interposer 110 and attached PIC 122 are transferred from the temporary carrier 119 to a silicon carrier 128 (which could also be temporary or permanent depending on the packaging configuration). A coupler 130 is also communicatively coupled to the PIC 122 in this phase. In some embodiments, the coupler 130 may be mechanically attached to the EIC interposer 110 and/or PIC 122 and/or placed adjacent thereto. In the embodiment depicted, the coupler 130 is placed on the silicon carrier 128. In various embodiments, the coupler 130 may be adapted to connect to a fiber optic cable (such as a fiber array unit or a fiber pigtail) comprising a coupler that mates with coupler 130. In other embodiments, the coupler 130 may include any suitable coupler to connect to a medium (e.g., a fiber cable) that can communicate optic signals (e.g., to another IC device). In some examples, a coupler may comprise a receptacle, socket, or other suitable connector.

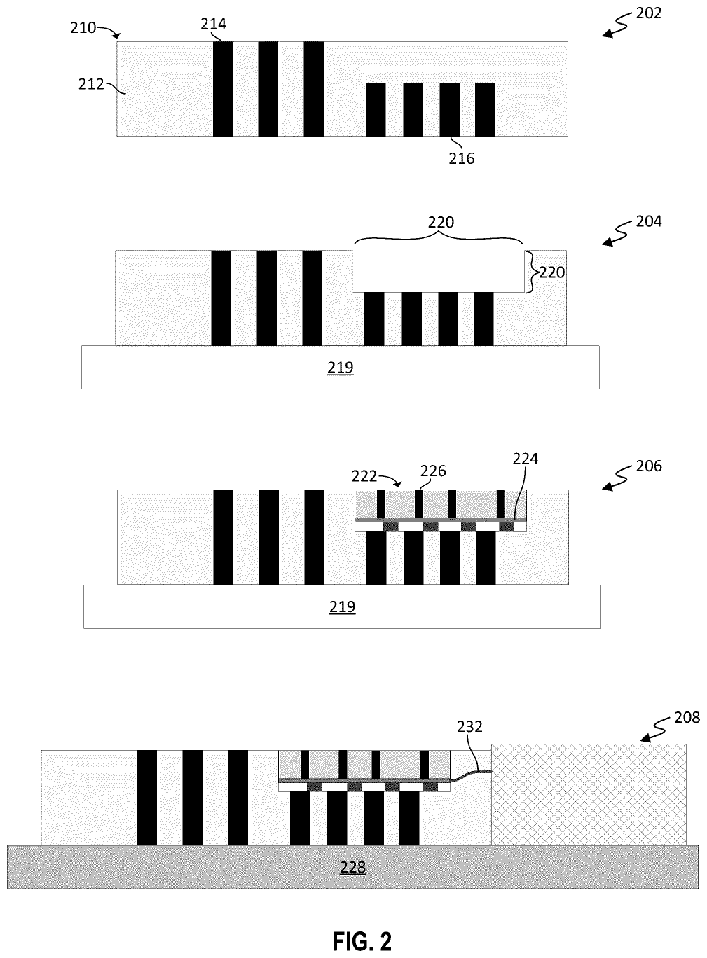

FIG. 2 illustrates example phases of manufacture of an example downward facing PIC within a cavity of an interposer with a glass substrate.

Phase 202 depicts an interposer 210 with a substrate 212 comprising glass (e.g., the substrate may be predominately comprised of glass) or other transparent material (e.g., a polymer with suitable optical and mechanical properties). In some embodiments, the substrate may comprise bulk transparent glass, which is different from fiberglass (e.g., as in fiberglass reinforced epoxy cores typically used in package substrates or motherboards) and opaque polycrystalline ceramic glass (e.g., which are generally used in high-temperature applications). In some embodiments, the glass is not combined with any organic material. The glass may comprise any type of bulk transparent glass with the appropriate refractive index, absorbance, transmittance, reflectivity, and other material properties suitable for optical communication, such as fused silica, borosilicate glass, transparent ceramic glass, or other suitable glass.

In various embodiments, use of a glass interposer may provide additional flexibility in the placement of the coupler, as the coupler need not be adjacent to the active region of the PIC (since a waveguide and/or other components may be used to route the light through the glass to the coupler).

The interposer 210 may comprise vias 214 and 216 (e.g., through-glass-vias enabling power, ground, and/or signal connectivity to components coupled via conductive contacts to either side of the substrate 212) with different depths. For example, in the shown phase, the vias 214 may extend to the top of substrate 212 of interposer 210 while the vias 216 only extend part of the way through the substrate 212 of the interposer 210. The shorter vias 216 may be placed in a region in which a cavity in the interposer 210 is to be formed.

In phase 204, a portion of the substrate 212 is removed to form a cavity 220 in the interposer 210. The portion of the substrate 212 may be removed using any suitable method (e.g., through a dry etch). After cavity 220 is formed, vias 216 may extend up to the bottom of the cavity 220.

In phase 206, PIC 222 is placed within cavity 220 and is attached to the interposer 210. The PIC 222 may be attached to the interposer 210 using any suitable method, such as through solder and underfill, TCNCP, or a liquid metal socket. A singulation step may also be performed. In some embodiments, a singulation step may also be performed during this phase. In various embodiments, the PIC may be attached to the interposer on a wafer level and once the PIC is attached to the interposer, the interposer wafer may be singulated.

The PIC 222 may include an active region 224 and vias 226 (e.g., similar to PIC 122). In this embodiment, the PIC 222 may be attached to the interposer 210 with the active region 224 facing downwards (e.g., proximate the bottom of the cavity 220 that is now occupied at least in part by the PIC 222).

In phase 208, the interposer 210 and attached PIC 222 are transferred from the glass carrier 219 to a silicon carrier 228. A coupler 230 is also communicatively coupled to the PIC 222 in this phase. In this embodiment, the coupler 230 is also placed on the silicon carrier 228.

A waveguide 232 is also written in the glass substrate 212 to connect the PIC 222 to the coupler 230 (e.g., the waveguide 232 may couple to the active region 224). The waveguide 232 may be formed in any suitable manner, such as by lithography or laser scribing. In some embodiments, a technique known as direct laser writing (DLW) may be used to generate waveguides with three dimensional (3D) structures within glass substrates.

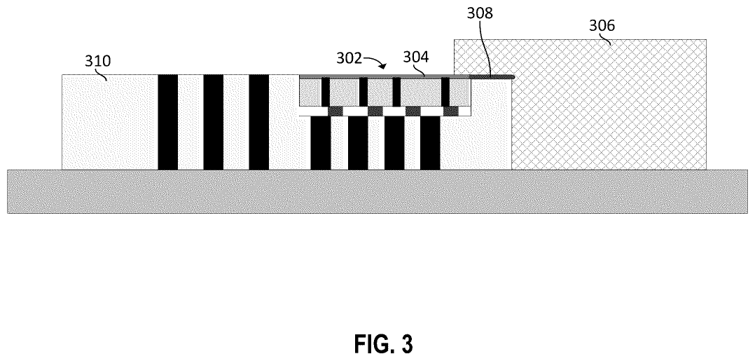

FIG. 3 illustrates an example upward facing PIC within a cavity of an interposer with a glass substrate. This embodiment may be similar to the embodiment of FIG. 2, but in FIG. 3 the PIC 302 comprises an active region 304 facing upward (e.g., at its top), rather than downward. In some embodiments, the coupler 306 may also have an alternate shape. For example, the coupler 306 may include a portion that extends over above a portion of the PIC 302 and a portion that is on the side of the PIC 302 (with a portion of the substrate 310 in between the PIC 302 and the coupler 306). A surface coupling 308 (e.g., a v-groove feature or other passive alignment feature) or waveguide may also be formed at or proximate the surface of the glass substrate 310 to couple the active region 304 to the coupler 306.

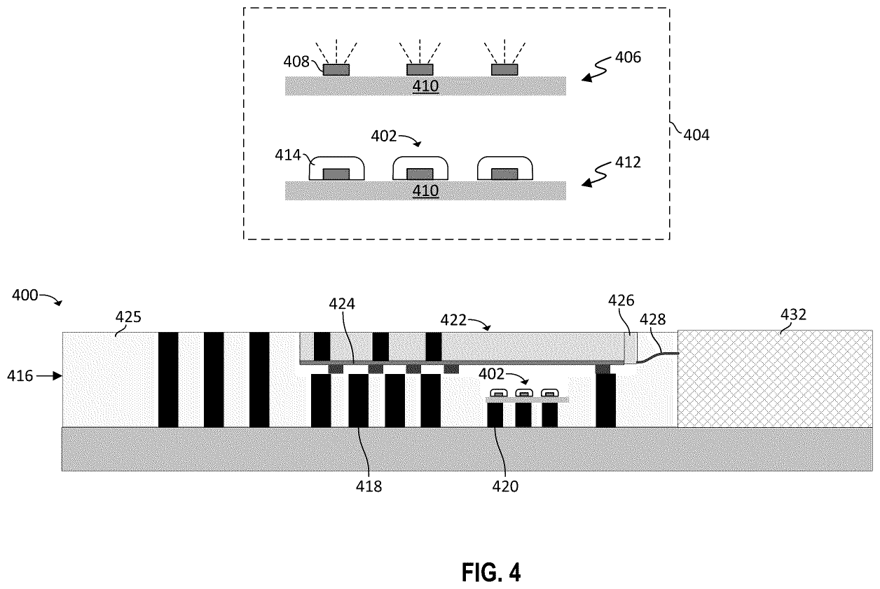

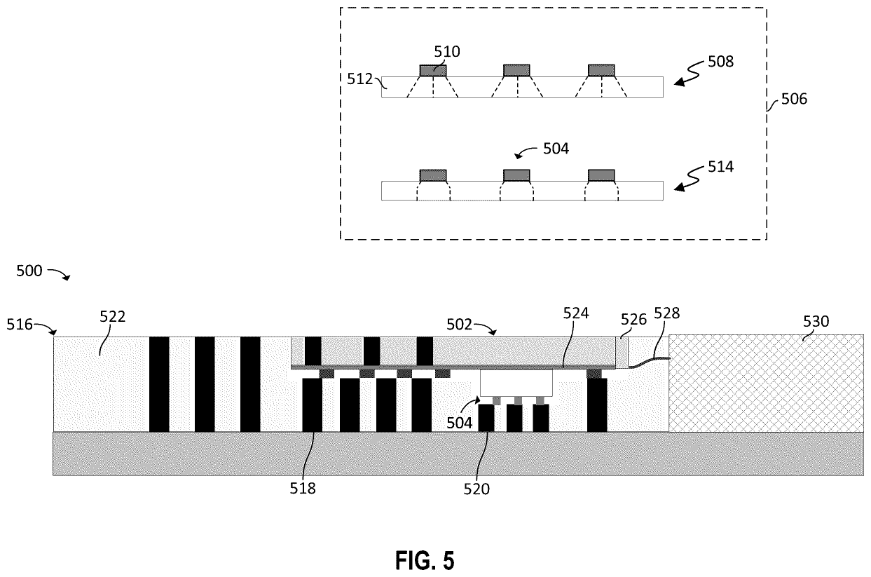

FIG. 4 illustrates an example PIC and integrated light source within a cavity of an interposer with a glass substrate. While in some embodiments a light source (e.g., laser source) may be external (e.g., part of a component (e.g., a coupler) or IC device coupled to the interposer), in the embodiments of FIGS. 4 and 5, the light source may be integrated with the PIC and interposer assembly 400 or 500.

In the embodiment depicted in FIG. 4, the PIC and interposer assembly 400 comprises an integrated light source 402. Phases of manufacture of the integrated light source 402 are shown in box 404. At phase 406, a micro light emitting diode (LED) array comprising microLEDs 408 is transfer printed onto a carrier substrate 410. At phase 412, microlenses 414 are formed using microdroplet printing on the microLEDs 408. The microlenses 414 may facilitate beam collimation by focusing optical signals generated by the microLEDs 408.

In the depicted embodiment, a cavity formed in the interposer 416 may include two levels (e.g., a first level at the top of vias 418 and a second level at the top of vias 420). The integrated light source 402 may be attached at one of these levels and the PIC 422 may be attached at the other level. In various embodiments, the integrated light source 402 may be attached to the interposer 416 first (e.g., by transfer printing or other suitable method) and then the PIC 422 may be attached (e.g., using solder, TCNCP, or other suitable method). In various embodiments, the PIC 422 may be attached to the interposer such that a portion of the PIC 422 is above the integrated light source 402 with the active region 424 facing the integrated light source 402. Thus, light source 402 may be integrated within the cavity of the interposer 416.

In various embodiments, a gap between the PIC 422 and a sidewall of the glass substrate 425 may be filled with a material 426 (e.g., an epoxy) that approximately matches a refractive index of the substrate material of the PIC and/or the glass substrate 425 to mitigate loss through the gap. A waveguide 428 may also be formed to connect a light path between the PIC 422 and the coupler 432.

In alternative embodiments, other types of light sources (e.g., laser arrays) may be used in place of the microLEDs 408 and microlenses 414 as the integrated light source in embodiments such as that shown in FIGS. 4 and 5 and variations thereof.

FIG. 5 illustrates another example PIC 502 and integrated light source 504 within a cavity of an interposer 516 with a glass substrate 522. Phases of manufacture of the integrated light source 504 are shown in box 506. At phase 508, a microLED array comprising microLEDs 510 is transfer printed upside down onto a glass carrier substrate 512 (such that light emitted by the microLEDs will travel into the glass). At phase 514, one or more waveguides are formed in the glass carrier substrate 512 to collimate beams emitted by the microLEDs. Example boundary paths for the light are shown as dotted lines.

Again, in this embodiment, the cavity formed in the interposer 516 may include two levels (e.g., a first level at the top of vias 518 and a second level at the top of vias 520). The integrated light source 504 may be attached at one of these levels and the PIC 502 may be attached at the other level. In various embodiments, the integrated light source may be attached first (e.g., by transfer printing the microLEDs onto the substrate 522 of the interposer 516 with a glass block (e.g., 512) on top or via other suitable method). The waveguide(s) may then be formed in the glass block (e.g., to collimate the beam from the microLEDs and to match the mode with a waveguide of the PIC 502). The PIC 502 may then be attached (e.g., using solder, TCNCP, or other suitable method) to the interposer such that the active region 524 of the PIC 502 faces the integrated light source 504.

In various embodiments, a gap between the PIC 502 and a sidewall of the glass substrate 522 (formed during creation of the cavity) may be filled with a material 526 (e.g., an epoxy) that approximately matches an index of the active region 524 of the PIC 502 and/or the glass substrate 522. A waveguide 528 may also be formed to connect a light path between the PIC 502 and the coupler 530.

In alternative embodiments, other types of light sources (e.g., laser arrays) may be used in place of the microLEDs 510 in embodiments such as that shown in FIG. 5 and variations thereof.

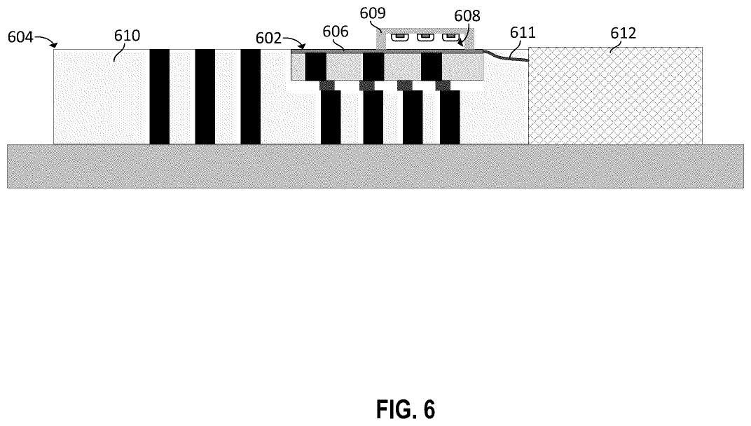

FIG. 6 illustrates an example integrated light source and upward facing PIC within a cavity of an interposer with a glass substrate. In this embodiment, instead of attaching the PIC 602 to the interposer 604 with the active region 606 of the PIC 602 facing downwards, the active region 606 faces upwards. A light source 608 is then attached (e.g., on a carrier 609 providing structural support) on the top side of the PIC 602 and may emit light towards the active region 606. A waveguide 611 may also be formed in the glass substrate 610 to connect the light path from the PIC 602 to the coupler 612.

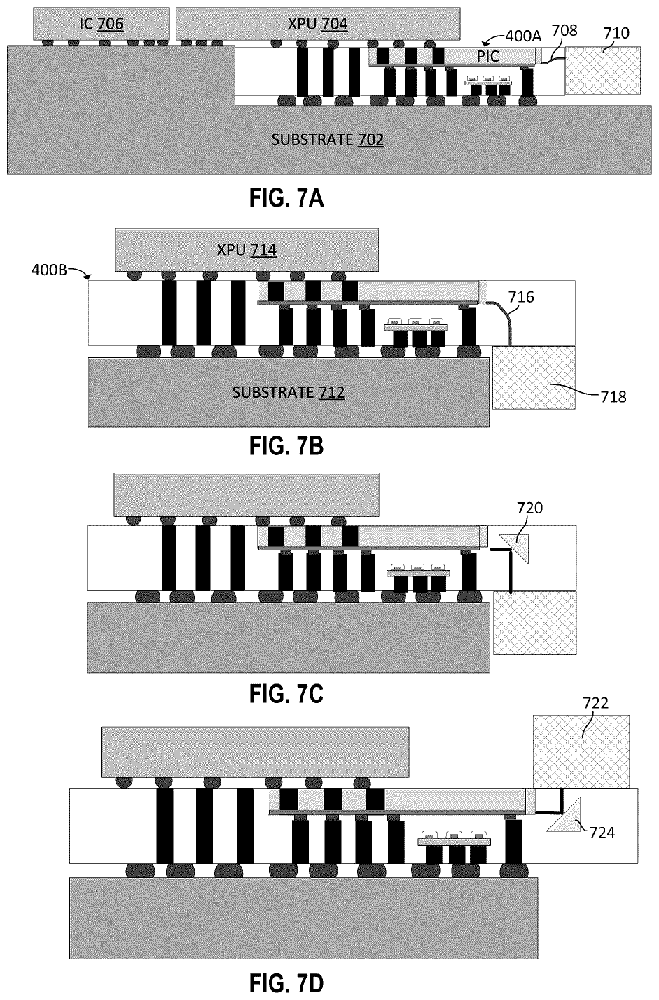

FIGS. 7A-7D illustrate example package level integrations for a PIC within a cavity of an interposer. FIG. 7A depicts PIC and interposer assembly 400A (where assembly 400A may have any suitable characteristics of assembly 400) placed within a cavity of a package substrate 702 and connected to the substrate 702. The substrate 702 may comprise, e.g., an organic substrate or a Laurentide substrate (which may provide improved warpage characteristics such as flatness). Although not shown, the substrate 702 may include conductive contacts on its bottom surface (e.g., for connection to a printed circuit board, such as a mother board) as well as conductive contacts on its top surface(s) that couple to conductive contacts (e.g., of one or more of the integrated circuit devices attached to the package substrate. In some embodiments, certain conductive contacts of the top surface(s) of the substrate 702 may be coupled to certain conductive contacts of the bottom surface of the substrate.

In FIG. 7A, an XPU 704 (examples of XPUs are described below) may be above at least a portion of the PIC and interposer assembly 400A and an upper level of the substrate 702. The XPU 704 may be connected to the assembly 400A as well as the substrate 702 (e.g., some conductive contacts of the XPU 704 may connect to conductive contacts of the assembly 400A while other conductive contacts of the XPU 704 may connect to conductive contacts of the substrate 702).

In some embodiments, one or more other integrated circuit devices 706 may also be connected to the substrate 702 (e.g., on top of the substrate 702 and to the side of the XPU 704).

A waveguide 708 may couple light from the active region of the PIC through a glass substrate of the assembly 400A to a coupler 710 attached to the side of the glass substrate of the assembly.

FIG. 7B depicts PIC and interposer assembly 400B placed on top of and connected to a package substrate 712 (where assembly 400B may have any suitable characteristics of assembly 400). An XPU 714 is placed above and connected to the assembly 400B.

A waveguide 716 may couple light from an active region of a PIC of the assembly 400B through a glass substrate of the assembly 400B to a coupler 718 that is attached to the bottom of the glass substrate of the assembly 400B of the assembly. The waveguide 716 may change the path of the light from a generally horizontal direction close to the PIC to a generally vertical direction close to the coupler 718 (thus converting a light beam from lateral to vertical in some embodiments).

FIG. 7C is similar to the embodiment of FIG. 7B, but includes a mirror 720 within the glass substrate to change the light path from horizontal to vertical (and vice versa for light received from the coupler) within the glass substrate.

FIG. 7D is similar to the embodiments of FIGS. 7B and 7C except the coupler 722 is placed on top of the glass substrate and the mirror 724 changes the light path from horizontal to vertical in the upward direction (or from vertically downward to horizontal in the opposite direction).

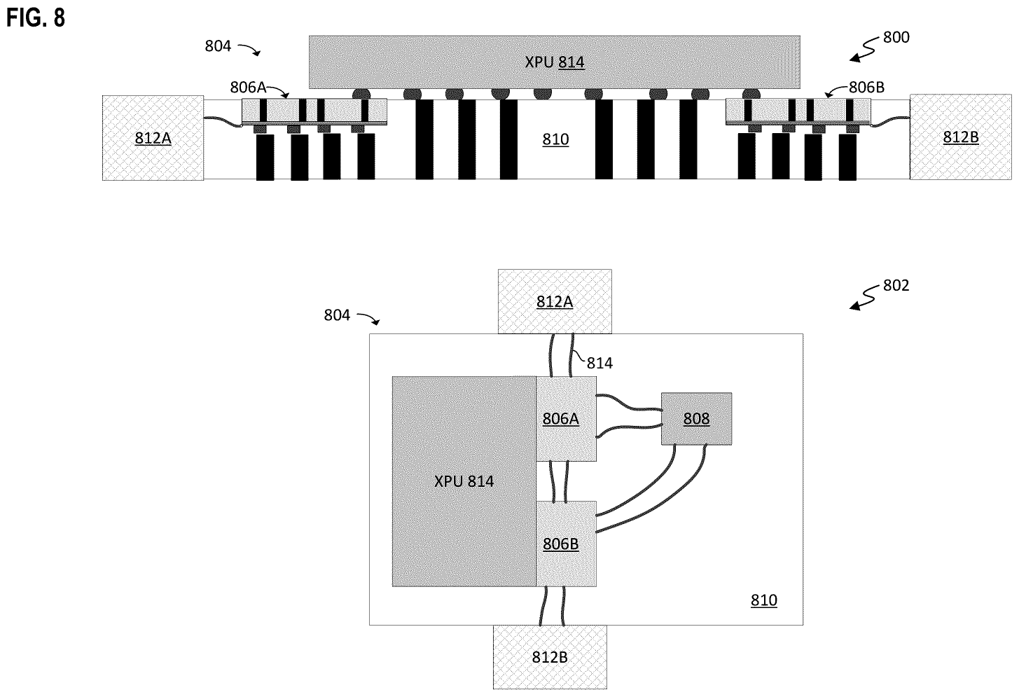

FIG. 8 illustrates multiple PICs in cavities of an example interposer. In some embodiments, a plurality (e.g., a matrix) of PICs may be integrated within cavities of an interposer for improved system integration. FIG. 8 illustrates a side view 800 and a top-down view 802 of a system 804 comprising two PICs 806 (806A and 806B) and a light source 808 placed within cavities of interposer 810 (in some embodiments the light source 808 may be placed in an additional cavity formed in the interposer 810). In various embodiments, the interposer 810 may comprise a glass substrate with waveguides 814 formed between the light source 808 and each PIC 806, between the PICs themselves, and between each PIC and the closest coupler 812 (812A or 812B), which may be attached or placed next to the interposer 810 on each side of the substrate of the interposer 810.

As depicted in view 802, the PICs 806 are each attached to the interposer 810 within cavities formed in the interposer 810. Although not visible because the laser is behind the PIC 806A in view 802, the light source 808 may be attached to the interposer 810 within a similar cavity formed in the interposer 810. The system 804 also includes an XPU 816 that is above and connected to the interposer 810 and both PICs 806.

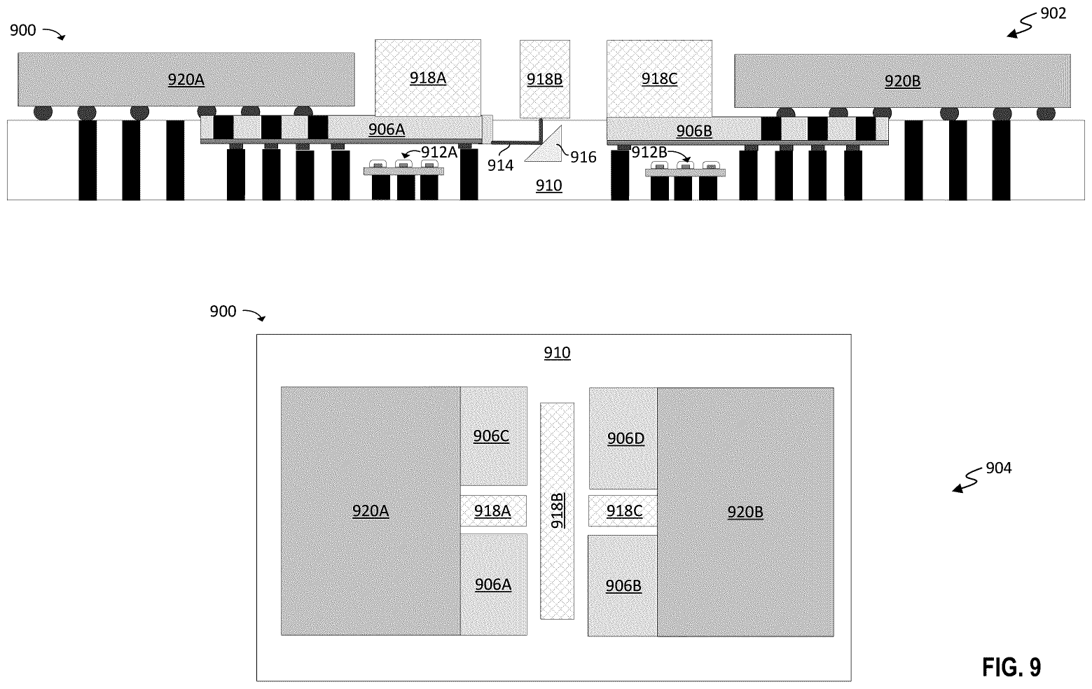

FIG. 9 illustrates multiple PICs in cavities of an example interposer with a glass substrate and integrated light sources. The integrated light sources may result in even shorter light connection paths in the system 900.

FIG. 9 illustrates a side view 902 and a top-down view 904 of system 900 comprising four PICs 906 (906A-D) placed within cavities of interposer 910. System 900 may include one or more integrated light sources 912. The light source 912A may direct light to a PIC 906A and the light may follow a path 914 within a glass substrate of the interposer 910 to a mirror 916 and then up to a coupler 918B. Although not shown, light from another light source 912B may similarly be directed to PIC 906B and then to a coupler (e.g., 918C).

The PICs 906 are each attached to the interposer 910 within cavities formed in the interposer 910. The system 900 also includes two XPUs 920A and B that are each above and connected to the interposer 910 and are each above and connected to a pair of respective PICS 906. For example, the XPU 920A is connected to PIC 906A and 906C while the XPU 920B is connected to PIC 906B and 906D.

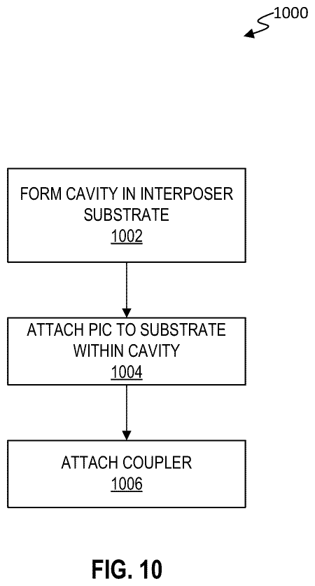

FIG. 10 illustrates an example process for forming a PIC within a cavity of an interposer. At 1002, a cavity is formed in an interposer substrate. At 1004, a PIC is placed within the cavity and attached to the interposer substrate. At 1006, a coupler is attached to the interposer substrate and/or the PIC (and may be communicatively coupled to an active region of the PIC).

Although FIG. 10 shows example blocks of process 1000, in some implementations, process 1000 may include additional blocks, fewer blocks, different blocks, or differently arranged blocks than those depicted in FIG. 10. Additionally, or alternatively, two or more of the blocks of process 1000 may be performed in parallel.

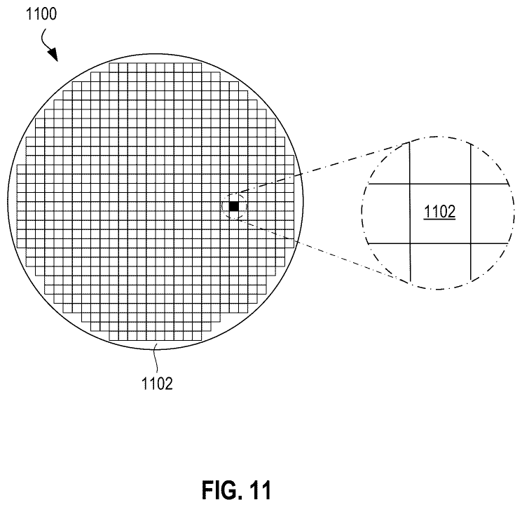

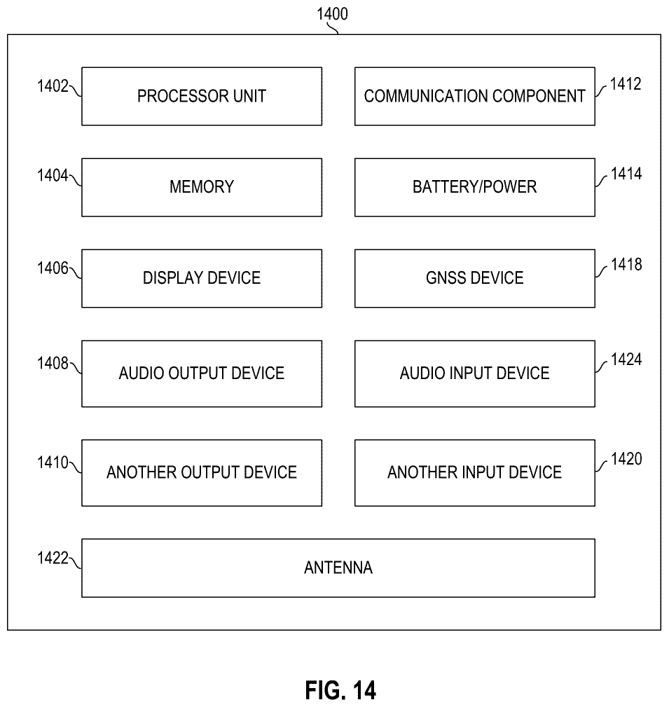

FIG. 11 is a top view of a wafer 1100 and dies 1102 wherein individual dies may include interposers with cavities, PICs, or other integrated circuits referenced herein. The wafer 1100 may be composed of semiconductor material and may include one or more dies 1102 having integrated circuit structures formed on a surface of the wafer 1100. The individual dies 1102 may be a repeating unit of an integrated circuit product that includes any suitable integrated circuit. After the fabrication of the semiconductor product is complete, the wafer 1100 may undergo a singulation process in which the dies 1102 are separated from one another to provide discrete “chips” of the integrated circuit product. The die 1102 may include one or more transistors supporting circuitry to route electrical signals to the transistors, passive components (e.g., signal traces, resistors, capacitors, or inductors), and/or any other integrated circuit components. In some embodiments, the wafer 1100 or the die 1102 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1102. For example, a memory array formed by multiple memory devices may be formed on a same die 1102 as a processor unit (e.g., the processor unit 1402 of FIG. 14) or other logic that is configured to store information in the memory devices or execute instructions stored in the memory array. Various ones of the microelectronic assemblies disclosed herein may be manufactured using a die-to-wafer assembly technique in which some dies are attached to a wafer 1100 that include other dies, and the wafer 1100 is subsequently singulated.

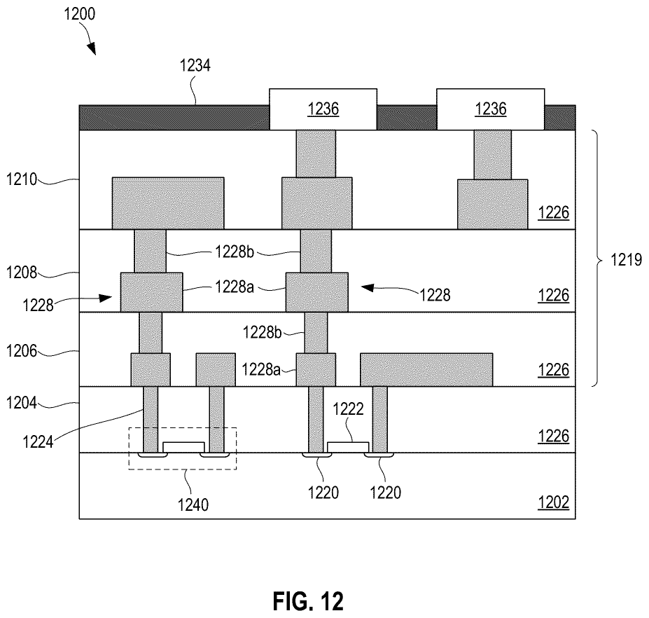

FIG. 12 is a cross-sectional side view of an integrated circuit device 1200 that may include interposers with cavities, PICs, or other integrated circuit device components referenced herein. One or more of the integrated circuit devices 1200 may be included in one or more dies 1102 (FIG. 11). The integrated circuit device 1200 may be formed on a die substrate 1202 (e.g., the wafer 1100 of FIG. 11) and may be included in a die (e.g., the die 1102 of FIG. 11). The die substrate 1202 may be a semiconductor substrate composed of semiconductor material systems including, for example, n-type or p-type materials systems (or a combination of both). The dic substrate 1202 may include, for example, a crystalline substrate formed using a bulk silicon or a silicon-on-insulator (SOI) substructure. In some embodiments, the die substrate 1202 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1202. Although a few examples of materials from which the die substrate 1202 may be formed are described here, any material that may serve as a foundation for an integrated circuit device 1200 may be used. The die substrate 1202 may be part of a singulated die (e.g., the dies 1102 of FIG. 11) or a wafer (e.g., the wafer 1100 of FIG. 11).

The integrated circuit device 1200 may include one or more device layers 1204 disposed on the die substrate 1202. The device layer 1204 may include features of one or more transistors 1240 (e.g., metal oxide semiconductor field-effect transistors (MOSFETs)) formed on the die substrate 1202. The transistors 1240 may include, for example, one or more source and/or drain (S/D) regions 1220, a gate 1222 to control current flow between the S/D regions 1220, and one or more S/D contacts 1224 to route electrical signals to/from the S/D regions 1220. The transistors 1240 may include additional features not depicted for the sake of clarity, such as device isolation regions, gate contacts, and the like. The transistors 1240 are not limited to the type and configuration depicted in FIG. 12 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

A transistor 1240 may include a gate 1222 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1240 is to be a p-type metal oxide semiconductor (PMOS) or an n-type metal oxide semiconductor (NMOS) transistor. In some implementations, the gate electrode may consist of or comprise a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1240 along the source-channel-drain direction, the gate electrode may consist of or comprise a U-shaped structure that includes a bottom portion substantially parallel to the surface of the die substrate 1202 and two sidewall portions that are substantially perpendicular to the top surface of the die substrate 1202. In other embodiments, at least one of the metal layers that form the gate electrode may simply be a planar layer that is substantially parallel to the top surface of the die substrate 1202 and does not include sidewall portions substantially perpendicular to the top surface of the die substrate 1202. In other embodiments, the gate electrode may consist of or comprise a combination of U-shaped structures and planar, non-U-shaped structures. For example, the gate electrode may consist of or comprise one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1220 may be formed within the die substrate 1202 adjacent to the gate 1222 of individual transistors 1240. The S/D regions 1220 may be formed using an implantation/diffusion process or an etching/deposition process, for example. In the former process, dopants such as boron, aluminum, antimony, phosphorous, or arsenic may be ion-implanted into the die substrate 1202 to form the S/D regions 1220. An annealing process that activates the dopants and causes them to diffuse farther into the die substrate 1202 may follow the ion-implantation process. In the latter process, the die substrate 1202 may first be etched to form recesses at the locations of the S/D regions 1220. An epitaxial deposition process may then be carried out to fill the recesses with material that is used to fabricate the S/D regions 1220. In some implementations, the S/D regions 1220 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1220 may be formed using one or more alternate semiconductor materials such as germanium or a group III-V material or alloy. In further embodiments, one or more layers of metal and/or metal alloys may be used to form the S/D regions 1220.

Electrical signals, such as power and/or input/output (I/O) signals, may be routed to and/or from the devices (e.g., transistors 1240) of the device layer 1204 through one or more interconnect layers disposed on the device layer 1204 (illustrated in FIG. 12 as interconnect layers 1206-1210). For example, electrically conductive features of the device layer 1204 (e.g., the gate 1222 and the S/D contacts 1224) may be electrically coupled with the interconnect structures 1228 of the interconnect layers 1206-1210. The one or more interconnect layers 1206-1210 may form a metallization stack (also referred to as an “ILD stack”) 1219 of the integrated circuit device 1200.

The interconnect structures 1228 (e.g., lines) may be arranged within the interconnect layers 1206-1210 to route electrical signals according to a wide variety of designs; in particular, the arrangement is not limited to the particular configuration of interconnect structures 1228 depicted in FIG. 12. Although a particular number of interconnect layers 1206-1210 is depicted in FIG. 12, embodiments of the present disclosure include integrated circuit devices having more or fewer interconnect layers than depicted.

In some embodiments, the interconnect structures 1228 may include lines 1228a and/or vias 1228b filled with an electrically conductive material such as a metal. The lines 1228a may be arranged to route electrical signals in a direction of a plane that is substantially parallel with a surface of the die substrate 1202 upon which the device layer 1204 is formed. For example, the lines 1228a may route electrical signals in a direction in and out of the page and/or in a direction across the page. The vias 1228b may be arranged to route electrical signals in a direction of a plane that is substantially perpendicular to the surface of the die substrate 1202 upon which the device layer 1204 is formed. In some embodiments, the vias 1228b may electrically couple lines 1228a of different interconnect layers 1206-1210 together.

The interconnect layers 1206-1210 may include a dielectric material 1226 disposed between the interconnect structures 1228, as shown in FIG. 12. In some embodiments, dielectric material 1226 disposed between the interconnect structures 1228 in different ones of the interconnect layers 1206-1210 may have different compositions; in other embodiments, the composition of the dielectric material 1226 between different interconnect layers 1206-1210 may be the same. The device layer 1204 may include a dielectric material 1226 disposed between the transistors 1240 and a bottom layer of the metallization stack as well. The dielectric material 1226 included in the device layer 1204 may have a different composition than the dielectric material 1226 included in the interconnect layers 1206-1210; in other embodiments, the composition of the dielectric material 1226 in the device layer 1204 may be the same as a dielectric material 1226 included in any one of the interconnect layers 1206-1210.

A first interconnect layer 1206 (referred to as Metal 1 or “M1”) may be formed directly on the device layer 1204. In some embodiments, the first interconnect layer 1206 may include lines 1228a and/or vias 1228b, as shown. The lines 1228a of the first interconnect layer 1206 may be coupled with contacts (e.g., the S/D contacts 1224) of the device layer 1204. The vias 1228b of the first interconnect layer 1206 may be coupled with the lines 1228a of a second interconnect layer 1208.

The second interconnect layer 1208 (referred to as Metal 2 or “M2”) may be formed directly on the first interconnect layer 1206. In some embodiments, the second interconnect layer 1208 may include via 1228b to couple the interconnect structures 1228 of the second interconnect layer 1208 with the lines 1228a of a third interconnect layer 1210. Although the lines 1228a and the vias 1228b are structurally delineated with a line within individual interconnect layers for the sake of clarity, the lines 1228a and the vias 1228b may be structurally and/or materially contiguous (e.g., simultaneously filled during a dual-damascene process) in some embodiments.

The third interconnect layer 1210 (referred to as Metal 3 or “M3”) (and additional interconnect layers, as desired) may be formed in succession on the second interconnect layer 1208 according to similar techniques and configurations described in connection with the second interconnect layer 1208 or the first interconnect layer 1206. In some embodiments, the interconnect layers that are “higher up” in the metallization stack 1219 in the integrated circuit device 1200 (e.g., farther away from the device layer 1204) may be thicker that the interconnect layers that are lower in the metallization stack 1219, with lines 1228a and vias 1228b in the higher interconnect layers being thicker than those in the lower interconnect layers.

The integrated circuit device 1200 may include a solder resist material 1234 (e.g., polyimide or similar material) and one or more conductive contacts 1236 formed on the interconnect layers 1206-1210. In FIG. 12, the conductive contacts 1236 are illustrated as taking the form of bond pads. The conductive contacts 1236 may be electrically coupled with the interconnect structures 1228 and configured to route the electrical signals of the transistor(s) 1240 to external devices. For example, solder bonds may be formed on the one or more conductive contacts 1236 to mechanically and/or electrically couple an integrated circuit die including the integrated circuit device 1200 with another component (e.g., a printed circuit board). The integrated circuit device 1200 may include additional or alternate structures to route the electrical signals from the interconnect layers 1206-1210; for example, the conductive contacts 1236 may include other analogous features (e.g., posts) that route the electrical signals to external components.

In some embodiments in which the integrated circuit device 1200 is a double-sided die, the integrated circuit device 1200 may include another metallization stack (not shown) on the opposite side of the device layer(s) 1204. This metallization stack may include multiple interconnect layers as discussed above with reference to the interconnect layers 1206-1210, to provide conductive pathways (e.g., including conductive lines and vias) between the device layer(s) 1204 and additional conductive contacts (not shown) on the opposite side of the integrated circuit device 1200 from the conductive contacts 1236.

In other embodiments in which the integrated circuit device 1200 is a double-sided die, the integrated circuit device 1200 may include one or more through silicon vias (TSVs) through the die substrate 1202; these TSVs may make contact with the device layer(s) 1204, and may provide conductive pathways between the device layer(s) 1204 and additional conductive contacts (not shown) on the opposite side of the integrated circuit device 1200 from the conductive contacts 1236. In some embodiments, TSVs extending through the substrate can be used for routing power and ground signals from conductive contacts on the opposite side of the integrated circuit device 1200 from the conductive contacts 1236 to the transistors 1240 and any other components integrated into the integrated circuit device (e.g., die) 1200, and the metallization stack 1219 can be used to route I/O signals from the conductive contacts 1236 to transistors 1240 and any other components integrated into the integrated circuit device (e.g., die) 1200.

Multiple integrated circuit devices 1200 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

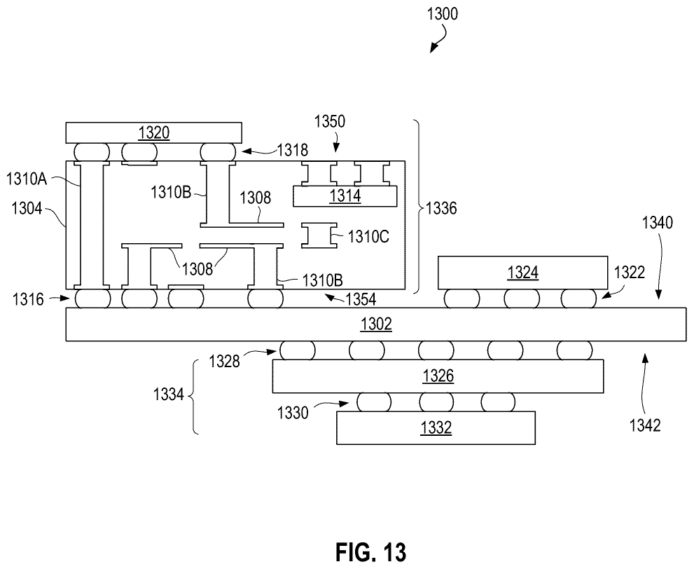

FIG. 13 is a cross-sectional side view of an integrated circuit device assembly 1300 that may include a PIC within a cavity of an interposer as described herein. The integrated circuit device assembly 1300 includes a number of components disposed on a circuit board 1302 (which may be a motherboard, system board, mainboard, etc.). The integrated circuit device assembly 1300 includes components disposed on a first face 1340 of the circuit board 1302 and an opposing second face 1342 of the circuit board 1302; generally, components may be disposed on one or both faces 1340 and 1342.

In some embodiments, the circuit board 1302 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1302. In other embodiments, the circuit board 1302 may be a non-PCB substrate. The integrated circuit device assembly 1300 illustrated in FIG. 13 includes a package-on-interposer structure 1336 coupled to the first face 1340 of the circuit board 1302 by coupling components 1316. The coupling components 1316 may electrically and mechanically couple the package-on-interposer structure 1336 to the circuit board 1302, and may include solder balls (as shown in FIG. 13), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1336 may include an integrated circuit component 1320 coupled to an interposer 1304 by coupling components 1318. The coupling components 1318 may take any suitable form for the application, such as the forms discussed above with reference to the coupling components 1316. Although a single integrated circuit component 1320 is shown in FIG. 13, multiple integrated circuit components may be coupled to the interposer 1304; indeed, additional interposers may be coupled to the interposer 1304. The interposer 1304 may provide an intervening substrate used to bridge the circuit board 1302 and the integrated circuit component 1320.

The integrated circuit component 1320 may be a packaged or unpackaged integrated circuit product that includes one or more integrated circuit dies (e.g., the die 1102 of FIG. 11, the integrated circuit device 1200 of FIG. 12) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1320, a single monolithic integrated circuit die comprises solder bumps attached to contacts on the die. The solder bumps allow the die to be directly attached to the interposer 1304. The integrated circuit component 1320 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1320 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1320 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1320 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1304 may spread connections to a wider pitch or reroute a connection to a different connection. For example, the interposer 1304 may couple the integrated circuit component 1320 to a set of ball grid array (BGA) conductive contacts of the coupling components 1316 for coupling to the circuit board 1302. In the embodiment illustrated in FIG. 13, the integrated circuit component 1320 and the circuit board 1302 are attached to opposing sides of the interposer 1304; in other embodiments, the integrated circuit component 1320 and the circuit board 1302 may be attached to a same side of the interposer 1304. In some embodiments, three or more components may be interconnected by way of the interposer 1304.

In some embodiments, the interposer 1304 may be formed as a PCB, including multiple metal layers separated from one another by layers of dielectric material and interconnected by electrically conductive vias. In some embodiments, the interposer 1304 may be formed of an epoxy resin, a fiberglass-reinforced epoxy resin, an epoxy resin with inorganic fillers, a ceramic material, or a polymer material such as polyimide. In some embodiments, the interposer 1304 may be formed of alternate rigid or flexible materials that may include the same materials described above for use in a semiconductor substrate, such as silicon, germanium, and other group III-V and group IV materials. The interposer 1304 may include metal interconnects 1308 and vias 1310, including but not limited to through hole vias 1310A (that extend from a first face 1350 of the interposer 1304 to a second face 1354 of the interposer 1304), blind vias 1310B (that extend from the first or second faces 1350 or 1354 of the interposer 1304 to an internal metal layer), and buried vias 1310C (that connect internal metal layers).

In some embodiments, the interposer 1304 can comprise a silicon interposer. Through silicon vias (TSV) extending through the silicon interposer can connect connections on a first face of a silicon interposer to an opposing second face of the silicon interposer. In some embodiments, an interposer 1304 comprising a silicon interposer can further comprise one or more routing layers to route connections on a first face of the interposer 1304 to an opposing second face of the interposer 1304.

The interposer 1304 may further include embedded devices 1314, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1304. The package-on-interposer structure 1336 may take the form of any of the package-on-interposer structures known in the art.

In some embodiments, the interposer 1304 may include any suitable characteristics of the interposers described herein. For example, the interposer 1304 may include one or more cavities into which PICs are placed and attached to the interposer.

The integrated circuit device assembly 1300 may include an integrated circuit component 1324 coupled to the first face 1340 of the circuit board 1302 by coupling components 1322. The coupling components 1322 may take the form of any of the embodiments discussed above with reference to the coupling components 1316, and the integrated circuit component 1324 may take the form of any of the embodiments discussed above with reference to the integrated circuit component 1320.

The integrated circuit device assembly 1300 illustrated in FIG. 13 includes a package-on-package structure 1334 coupled to the second face 1342 of the circuit board 1302 by coupling components 1328. The package-on-package structure 1334 may include an integrated circuit component 1326 and an integrated circuit component 1332 coupled together by coupling components 1330 such that the integrated circuit component 1326 is disposed between the circuit board 1302 and the integrated circuit component 1332. The coupling components 1328 and 1330 may take the form of any of the embodiments of the coupling components 1316 discussed above, and the integrated circuit components 1326 and 1332 may take the form of any of the embodiments of the integrated circuit component 1320 discussed above. The package-on-package structure 1334 may be configured in accordance with any of the package-on-package structures known in the art.

FIG. 14 is a block diagram of an example electrical device 1400 that may include one or more PICs disposed in one or more cavities of an interposer as described herein. For example, any suitable ones of the components of the electrical device 1400 may include one or more of the integrated circuit dies 1102, integrated circuit devices 1200, integrated circuit device assemblies 1300, integrated circuit components 1320, or other components disclosed herein. A number of components are illustrated in FIG. 14 as included in the electrical device 1400, but any one or more of these components may be omitted or duplicated, as suitable for the application. In some embodiments, some or all of the components included in the electrical device 1400 may be attached to one or more motherboards mainboards, or system boards. In some embodiments, one or more of these components are fabricated onto a single system-on-a-chip (SoC) die.

Additionally, in various embodiments, the electrical device 1400 may not include one or more of the components illustrated in FIG. 14, but the electrical device 1400 may include interface circuitry for coupling to the one or more components. For example, the electrical device 1400 may not include a display device 1406, but may include display device interface circuitry (e.g., a connector and driver circuitry) to which a display device 1406 may be coupled. In another set of examples, the electrical device 1400 may not include an audio input device 1424 or an audio output device 1408, but may include audio input or output device interface circuitry (e.g., connectors and supporting circuitry) to which an audio input device 1424 or audio output device 1408 may be coupled.

The electrical device 1400 may include one or more processor units 1402 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1402 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1400 may include a memory 1404, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1404 may include memory that is located on the same integrated circuit die as the processor unit 1402. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1400 can comprise one or more processor units 1402 that are heterogeneous or asymmetric to another processor unit 1402 in the electrical device 1400. There can be a variety of differences between the processing units 1402 in a system in terms of a spectrum of metrics of merit including architectural, microarchitectural, thermal, power consumption characteristics, and the like. These differences can effectively manifest themselves as asymmetry and heterogeneity among the processor units 1402 in the electrical device 1400.

In some embodiments, the electrical device 1400 may include a communication component 1412 (e.g., one or more communication components). For example, the communication component 1412 can manage wireless communications for the transfer of data to and from the electrical device 1400. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1412 may implement any of a number of wireless standards or protocols, including but not limited to Institute for Electrical and Electronic Engineers (IEEE) standards including Wi-Fi (IEEE 1202.11 family), IEEE 1202.16 standards (e.g., IEEE 1202.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 1202.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1202.16 standards. The communication component 1412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1412 may operate in accordance with Code Division Multiple Access (CDMA), Time Division Multiple Access (TDMA), Digital Enhanced Cordless

Telecommunications (DECT), Evolution-Data Optimized (EV-DO), and derivatives thereof, as well as any other wireless protocols that are designated as 3G, 4G, 5G, and beyond. The communication component 1412 may operate in accordance with other wireless protocols in other embodiments. The electrical device 1400 may include an antenna 1422 to facilitate wireless communications and/or to receive other wireless communications (such as amplitude modulation (AM) or frequency modulation (FM) radio transmissions).

In some embodiments, the communication component 1412 may manage wired communications, such as electrical, optical, or any other suitable communication protocols (e.g., IEEE 1202.3 Ethernet standards). As noted above, the communication component 1412 may include multiple communication components. For instance, a first communication component 1412 may be dedicated to shorter-range wireless communications such as Wi-Fi or Bluetooth, and a second communication component 1412 may be dedicated to longer-range wireless communications such as global positioning system (GPS), EDGE, GPRS, CDMA, WiMAX, LTE, EV-DO, or others. In some embodiments, a first communication component 1412 may be dedicated to wireless communications, and a second communication component 1412 may be dedicated to wired communications.

The electrical device 1400 may include battery/power circuitry 1414. The battery/power circuitry 1414 may include one or more energy storage devices (e.g., batteries or capacitors) and/or circuitry for coupling components of the electrical device 1400 to an energy source separate from the electrical device 1400 (e.g., AC line power).

The electrical device 1400 may include a display device 1406 (or corresponding interface circuitry, as discussed above). The display device 1406 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1400 may include an audio output device 1408 (or corresponding interface circuitry, as discussed above). The audio output device 1408 may include any embedded or wired or wirelessly connected external device that generates an audible indicator, such speakers, headsets, or earbuds.

The electrical device 1400 may include an audio input device 1424 (or corresponding interface circuitry, as discussed above). The audio input device 1424 may include any embedded or wired or wirelessly connected device that generates a signal representative of a sound, such as microphones, microphone arrays, or digital instruments (e.g., instruments having a musical instrument digital interface (MIDI) output). The electrical device 1400 may include a Global Navigation Satellite System (GNSS) device 1418 (or corresponding interface circuitry, as discussed above), such as a Global Positioning System (GPS) device. The GNSS device 1418 may be in communication with a satellite-based system and may determine a geolocation of the electrical device 1400 based on information received from one or more GNSS satellites, as known in the art.

The electrical device 1400 may include another output device 1410 (or corresponding interface circuitry, as discussed above). Examples of the other output device 1410 may include an audio codec, a video codec, a printer, a wired or wireless transmitter for providing information to other devices, or an additional storage device.

The electrical device 1400 may include another input device 1420 (or corresponding interface circuitry, as discussed above). Examples of the other input device 1420 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1400 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1400 may be any other electronic device that processes data. In some embodiments, the electrical device 1400 may comprise multiple discrete physical components. Given the range of devices that the electrical device 1400 can be manifested as in various embodiments, in some embodiments, the electrical device 1400 can be referred to as a computing device or a computing system.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

It will also be understood that, although the terms “first,” “second,” and so forth may be used herein to describe various elements, these elements should not be limited by these terms. These terms are only used to distinguish one element from another, and are not intended to imply that the objects so described must be in a given sequence, either temporally, spatially, in ranking or in any other manner. For example, a first contact could be termed a second contact, and, similarly, a second contact could be termed a first contact, without departing from the scope of the present example embodiments. The first contact and the second contact are both contacts, but they are not the same contact.

As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. For example, the phrase “A and/or B” means (A), (B), or (A and B), while the phrase “A, B, and/or C” means (A), (B), (C), (A and B), (A and C), (B and C), or (A, B, and C).

As used throughout this description, and in the claims, a list of items joined by the term “at least one of” or “one or more of” can mean any combination of the listed terms.

It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Furthermore, the terms “comprising,” “including,” “having,” and the like, as used with respect to embodiments of the present disclosure, are synonymous.

The description may use the phrases “in an embodiment,” “according to some embodiments,” “in accordance with embodiments,” or “in embodiments,” which may each refer to one or more of the same or different embodiments.

As used herein, the term “module” refers to being part of, or including an ASIC, an electronic circuit, a system on a chip, a processor (shared, dedicated, or group), a solid state device, a memory (shared, dedicated, or group) that execute one or more software or firmware programs, a combinational logic circuit, and/or other suitable components that provide the described functionality.

As used herein, “electrically conductive” in some examples may refer to a property of a material having an electrical conductivity greater than or equal to 10⁷ Siemens per meter (S/m) at 20 degrees Celsius. Examples of such materials include Cu, Ag. Al, Au, W, Zn and Ni.

The term “signal” may refer to at least one current signal, voltage signal, magnetic signal, or data/clock signal.

Throughout the specification, and in the claims, the term “connected” means a direct connection, such as electrical, mechanical, or magnetic connection between the elements that are connected, without any intermediary devices. The term “coupled” means a direct or indirect connection, such as a direct electrical, mechanical, or magnetic connection between the elements that are connected or an indirect connection, through one or more passive or active intermediary devices.

The description may use perspective-based descriptions such as top/bottom, in/out, over/under, and the like. Such descriptions are merely used to facilitate the discussion and are not intended to restrict the application of embodiments described herein to any particular orientation.

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer means that at least a part of the first material or layer is in direct physical contact with at least a part of that second material/layer. Similar distinctions are to be made in the context of component assemblies.

As used herein, “A is adjacent to B” means that at least part of A is in direct physical contact with at least a part of B.

As used herein, “A is proximate to B” may mean that A is adjacent to B or A is otherwise near to B.

Unless otherwise specified in the specific context of use, the term “predominantly” means more than 50%, or more than half. For example, a composition that is predominantly a first constituent means more than half of the composition (e.g., by volume) is the first constituent (e.g., >50 at. %). The term “primarily” means the most, or greatest, part. For example, a composition that is primarily a first constituent means the composition has more of the first constituent (e.g., by volume) than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

The terms “substantially,” “close,” “approximately,” “near,” and “about,” generally refer to being within +/−10% of a target value (unless specifically specified).

Unless otherwise specified in the explicit context of their use, the terms “substantially equal,” “about equal” or “approximately equal” mean that there is no more than incidental variation between two things so described. In the art, such variation is typically no more than +/−10% of a predetermined target value.

In the corresponding drawings of the embodiments, signals, currents, electrical biases, or magnetic or electrical polarities may be represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate casier understanding of a circuit or a logical unit. Any represented signal, polarity, current, voltage, etc., as dictated by design needs or preferences, may actually comprise one or more signals that may travel in either direction and may be implemented with any suitable type of signal scheme.

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements.

Although the figures may illustrate embodiments where structures are substantially aligned to Cartesian axes (e.g., device structures having substantially vertical sidewalls), positive and negative (re-entrant) sloped feature sidewalls often occur in practice. For example, manufacturing non-idealities may cause one or more structural features to have sloped sidewalls. Thus, attributes illustrated are idealized merely for the sake of clearly describing salient features. It is to be understood that schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

It will be understood that components that appear or are described in connection with a particular FIG. herein may have characteristics that may apply to similarly named components that appear in other FIGS.

Example 1 includes an apparatus comprising an interposer comprising first conductive contacts on a top surface of the interposer, second conductive contacts on a bottom surface of the interposer, and third conductive contacts on a surface of a cavity of the interposer; first vias coupling a first portion of the second conductive contacts to the first conductive contacts; and second vias coupling a second portion of the second conductive contacts to the third conductive contacts; and a photonics integrated circuit (PIC) within the cavity of the interposer and coupled to the third conductive contacts.

Example 2 includes the subject matter of Example 1, and wherein the interposer comprises a substrate comprising silicon.

Example 3 includes the subject matter of any of Examples 1 and 2, and wherein the interposer comprises a substrate comprising glass.

Example 4 includes the subject matter of any of Examples 1-3, and wherein the PIC comprises an active region proximate a first surface of the PIC, the active region to communicate an optical signal.

Example 5 includes the subject matter of any of Examples 1-4, and wherein the first surface of the PIC is oriented facing down towards the surface of the cavity.

Example 6 includes the subject matter of any of Examples 1-5, and wherein the first surface of the PIC is oriented facing up away from the surface of the cavity.

Example 7 includes the subject matter of any of Examples 1-6, and further including a light source within the cavity of the interposer.

Example 8 includes the subject matter of any of Examples 1-7, and wherein the light source comprises a microLED array.

Example 9 includes the subject matter of any of Examples 1-8, and further including a plurality of microlenses on microLEDs of the microLED array.

Example 10 includes the subject matter of any of Examples 1-9, and further including glass between the microLED array and an active region of the PIC, the glass comprising at least one waveguide.

Example 11 includes the subject matter of any of Examples 1-10, and wherein the interposer further comprises a mirror to change a path of the optical signal from lateral to vertical, and wherein the coupler is attached to the top surface or the bottom surface of the interposer.

Example 12 includes the subject matter of any of Examples 1-11, and wherein the light source comprises a laser.

Example 13 includes the subject matter of any of Examples 1-12, and further including a coupler attached to the interposer; and a waveguide of the interposer, the waveguide to communicate the optical signal between an active region of the PIC and the coupler.

Example 14 includes a system comprising a package to couple to a printed circuit board, the package comprising a substrate; an integrated circuit device; an interposer between at least a portion of the substrate and at least a portion of the integrated circuit device; and a photonics integrated circuit (PIC) within a cavity of the interposer.

Example 15 includes the subject matter of Example 14, and wherein the package further comprises a second integrated circuit coupled to the substrate.

Example 16 includes the subject matter of any of Examples 14 and 15, and further including the printed circuit board.

Example 17 includes the subject matter of any of Examples 14-16, and wherein the package further comprises a plurality of PICs within a plurality of cavities of the interposer.

Example 18 includes the subject matter of any of Examples 14-17, and wherein the interposer comprises a substrate comprising silicon.

Example 19 includes the subject matter of any of Examples 14-18, and wherein the interposer comprises a substrate comprising glass.

Example 20 includes the subject matter of any of Examples 14-19, and wherein the PIC comprises an active region proximate a first surface of the PIC, the active region to communicate an optical signal.

Example 21 includes the subject matter of any of Examples 14-20, and wherein the first surface of the PIC is oriented facing down towards the surface of the cavity.

Example 22 includes the subject matter of any of Examples 14-21, and wherein the first surface of the PIC is oriented facing up away from the surface of the cavity.

Example 23 includes the subject matter of any of Examples 14-22, and further including a light source within the cavity of the interposer.

Example 24 includes the subject matter of any of Examples 14-23, and wherein the light source comprises a microLED array.

Example 25 includes the subject matter of any of Examples 14-24, and further including a plurality of microlenses on microLEDs of the microLED array.

Example 26 includes the subject matter of any of Examples 14-25, and further including glass between the microLED array and an active region of the PIC, the glass comprising at least one waveguide.

Example 27 includes the subject matter of any of Examples 14-26, and wherein the interposer further comprises a mirror to change a path of an optical signal from lateral to vertical, and wherein a coupler is attached to the top surface or the bottom surface of the interposer.

Example 28 includes the subject matter of any of Examples 14-27, and wherein the light source comprises a laser.

Example 29 includes the subject matter of any of Examples 14-28, and further including a coupler attached to the interposer; and a waveguide of the interposer, the waveguide to communicate the optical signal between an active region of the PIC and the coupler.

Example 30 includes an apparatus comprising an interposer to couple conductive contacts of a substrate to conductive contacts of an integrated circuit device, wherein the interposer comprises a cavity proximate conductive contacts of the interposer, the conductive contacts of the interposer to couple to conductive contacts of a photonics integrated circuit (PIC).

Example 31 includes the subject matter of Example 30, and further including the PIC, wherein the PIC is disposed within the cavity.

Example 32 includes the subject matter of any of Examples 30 and 31, and wherein the interposer comprises first vias of a first length to couple to the conductive contacts of the integrated circuit device and second vias of a second length to couple to the conductive contacts of the PIC, wherein the second length is shorter than the first length.

Example 33 includes the subject matter of any of Examples 30-32, and wherein the interposer comprises a substrate comprising silicon.

Example 34 includes the subject matter of any of Examples 30-33, and wherein the interposer comprises a substrate comprising glass.

Example 35 includes the subject matter of any of Examples 30-34, and wherein the PIC comprises an active region proximate a first surface of the PIC, the active region to communicate an optical signal.

Example 36 includes the subject matter of any of Examples 30-35, and wherein the first surface of the PIC is oriented facing down towards the surface of the cavity.

Example 37 includes the subject matter of any of Examples 30-36, and wherein the first surface of the PIC is oriented facing up away from the surface of the cavity.

Example 38 includes the subject matter of any of Examples 30-37, and further including a light source within the cavity of the interposer.

Example 39 includes the subject matter of any of Examples 30-38, and wherein the light source comprises a microLED array.

Example 40 includes the subject matter of any of Examples 30-39, and further including a plurality of microlenses on microLEDs of the microLED array.

Example 41 includes the subject matter of any of Examples 30-40, and further including glass between the microLED array and an active region of the PIC, the glass comprising at least one waveguide.

Example 42 includes the subject matter of any of Examples 30-41, and wherein the interposer further comprises a mirror to change a path of an optical signal from lateral to vertical, and wherein a coupler is attached to the top surface or the bottom surface of the interposer.

Example 43 includes the subject matter of any of Examples 30-42, and wherein the light source comprises a laser.

Example 44 includes the subject matter of any of Examples 30-43, and further including a coupler attached to the interposer; and a waveguide of the interposer, the waveguide to communicate the optical signal between an active region of the PIC and the coupler.

Example 45 includes a method comprising forming an interposer to couple conductive contacts of a substrate to conductive contacts of an integrated circuit device, wherein the interposer comprises a cavity proximate conductive contacts of the interposer, the conductive contacts of the interposer to couple to conductive contacts of a photonics integrated circuit (PIC).

Example 46 includes the subject matter of Example 45, and further including attaching the PIC to the interposer within the cavity.

Example 47 includes the subject matter of any of Examples 45 and 46, and wherein the interposer comprises first vias of a first length to couple to the conductive contacts of the integrated circuit device and second vias of a second length to couple to the conductive contacts of the PIC, wherein the second length is shorter than the first length.

Example 48 includes the subject matter of any of Examples 45-47, and wherein the interposer comprises a substrate comprising silicon.

Example 49 includes the subject matter of any of Examples 45-48, and wherein the interposer comprises a substrate comprising glass.

Example 50 includes the subject matter of any of Examples 45-49, and wherein the PIC comprises an active region proximate a first surface of the PIC, the active region to communicate an optical signal.

Example 51 includes the subject matter of any of Examples 45-50, and wherein the first surface of the PIC is oriented facing down towards the surface of the cavity.

Example 52 includes the subject matter of any of Examples 45-51, and wherein the first surface of the PIC is oriented facing up away from the surface of the cavity.

Example 53 includes the subject matter of any of Examples 45-52, and further including forming a light source within the cavity of the interposer.

Example 54 includes the subject matter of any of Examples 45-53, and wherein the light source comprises a microLED array.

Example 55 includes the subject matter of any of Examples 45-54, and further including forming a plurality of microlenses on microLEDs of the microLED array.

Example 56 includes the subject matter of any of Examples 45-55, and further including forming glass between the microLED array and an active region of the PIC, the glass comprising at least one waveguide.

Example 57 includes the subject matter of any of Examples 45-56, and wherein the interposer further comprises a mirror to change a path of an optical signal from lateral to vertical, and wherein a coupler is attached to the top surface or the bottom surface of the interposer.

Example 58 includes the subject matter of any of Examples 45-57, and wherein the light source comprises a laser.

Example 59 includes the subject matter of any of Examples 45-58, and further including attaching a coupler to the interposer; and forming a waveguide of the interposer, the waveguide to communicate the optical signal between an active region of the PIC and the coupler.

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

1. An apparatus comprising:
an interposer comprising:
first conductive contacts on a top surface of the interposer, second conductive contacts on a bottom surface of the interposer, and third conductive contacts on a surface of a cavity of the interposer;
first vias coupling a first portion of the second conductive contacts to the first conductive contacts; and
second vias coupling a second portion of the second conductive contacts to the third conductive contacts; and
a photonics integrated circuit (PIC) within the cavity of the interposer and coupled to the third conductive contacts.

2. The apparatus of claim 1, wherein the interposer comprises a substrate comprising silicon.

3. The apparatus of claim 1, wherein the interposer comprises a substrate comprising glass.

4. The apparatus of claim 1, wherein the PIC comprises an active region proximate a first surface of the PIC, the active region to communicate an optical signal.

5. The apparatus of claim 4, wherein the first surface of the PIC is oriented facing down towards the surface of the cavity.

6. The apparatus of claim 4, wherein the first surface of the PIC is oriented facing up away from the surface of the cavity.

7. The apparatus of claim 1, further comprising a light source within the cavity of the interposer.

8. The apparatus of claim 7, wherein the light source comprises a microLED array.

9. The apparatus of claim 8, further comprising a plurality of microlenses on microLEDs of the microLED array.

10. The apparatus of claim 8, further comprising glass between the microLED array and an active region of the PIC, the glass comprising at least one waveguide.

11. The apparatus of claim 8, wherein the interposer further comprises a mirror to change a path of an optical signal from lateral to vertical, and wherein a coupler is attached to the top surface or the bottom surface of the interposer.

12. The apparatus of claim 7, wherein the light source comprises a laser.

13. The apparatus of claim 1, further comprising:
a coupler attached to the interposer; and
a waveguide of the interposer, the waveguide to communicate the optical signal between an active region of the PIC and the coupler.

14. A system comprising:
a package to couple to a printed circuit board, the package comprising:
a substrate;
an integrated circuit device;
an interposer between at least a portion of the substrate and at least a portion of the integrated circuit device; and
a photonics integrated circuit (PIC) within a cavity of the interposer.

15. The system of claim 14, wherein the package further comprises a second integrated circuit coupled to the substrate.

16. The system of claim 14, further comprising the printed circuit board.

17. The system of claim 14, wherein the package further comprises a plurality of PICs within a plurality of cavities of the interposer.

18. An apparatus comprising:
an interposer to couple conductive contacts of a substrate to conductive contacts of an integrated circuit device, wherein the interposer comprises a cavity proximate conductive contacts of the interposer, the conductive contacts of the interposer to couple to conductive contacts of a photonics integrated circuit (PIC).

19. The apparatus of claim 18, further comprising the PIC, wherein the PIC is disposed within the cavity.

20. The apparatus of claim 18, wherein the interposer comprises first vias of a first length to couple to the conductive contacts of the integrated circuit device and second vias of a second length to couple to the conductive contacts of the PIC, wherein the second length is shorter than the first length.
